(19) United States
(12) Patent Application Publication
(10) Pub. No.: US 2020/0161339 A1
(43) Pub. Date: May 21, 2020

(54) SEMICONDUCTOR DEVICE

(71) Applicant: SAMSUNG ELECTRONICS CO., LTD., Suwon-si (KR)

(72) Inventors: Hyejoo LEE, Yongin-si (KR); Minsu Kim, Hwaseong-si (KR)

(21) Appl. No.: 16/525,776

(22) Filed: Jul. 30, 2019

(30) Foreign Application Priority Data
Nov. 15, 2018 (KR) 10-2018-0140402

(51) Int. Cl. H01L 27/12; H01L 27/092; H01L 21/84

(52) U.S. Cl. CPC H01L 27/1211; H01L 21/845; H01L 27/0924

(57) ABSTRACT

A semiconductor device includes a substrate, an insulating layer disposed on the substrate, and a first semiconductor structure and a second semiconductor structure disposed on the insulating layer. Each of the first and second semiconductor structures includes a gate electrode on the insulating layer, a plurality of channel layers that are surrounded by the gate electrode and stacked in a direction perpendicular to a top surface of the insulating layer, and a plurality of dielectric layers disposed between the gate electrode and the channel layers. The amount of the channel layers provided in the first semiconductor structure is greater than the amount of the channel layers provided in the second semiconductor structure.

### CROSS-REFERENCE TO RELATED APPLICATION

This application claims priority under 35 U.S.C. § 119 to Korean Patent Application No. 10-2018-0140402, filed on Nov. 15, 2018 in the Korean Intellectual Property Office (KIPO), the disclosure of which is incorporated by reference in its entirety herein.

### TECHNICAL FIELD

The present inventive concepts relate to a semiconductor device, and more particularly, to a semiconductor device including a plurality of channels.

### DISCUSSION OF RELATED ART

Semiconductor devices are important devices in the electronic industry due to their small size, multi-functionality, and/or low manufacturing cost. Semiconductor devices may encompass semiconductor memory devices that are configured to store logic data, semiconductor logic devices that are configured for processing operations of logic data, and hybrid semiconductor devices having both memory and logic elements. A high integration has been increasingly required for semiconductor devices as the development of the electronic industry has advanced. For example, it is required that semiconductor devices have high integration and include high-performance transistors. As semiconductor devices become highly integrated, it has become more difficult to manufacture high performance transistors which meet the customer's requirements has become more difficult to achieve.

### SUMMARY

Some exemplary embodiments of the present inventive concepts provide a semiconductor device with improved electrical characteristics.

According to an exemplary embodiment of the present inventive concepts, a semiconductor device includes a substrate. An insulating layer is disposed on the substrate. A first semiconductor structure and a second semiconductor structure are disposed on the insulating layer. Each of the first and second semiconductor structures includes: a gate electrode on the insulating layer; a plurality of channel layers that are surrounded by the gate electrode and stacked in a direction perpendicular to a top surface of the insulating layer; and a plurality of dielectric layers between the gate electrode and the channel layers. The amount of the channel layers provided in the first semiconductor structure is greater than the amount of the channel layers provided in the second semiconductor structure.

According to an exemplary embodiment of the present inventive concepts, a first transistor is disposed on an NMOS region of the substrate. A second transistor is disposed on a PMOS region of the substrate. Each of the first and second transistors includes: a first channel layer positioned at a first distance from a top surface of the substrate; a second channel layer positioned at a second distance from the top surface of the substrate, the second distance being greater than the first distance; and a plurality of source/drain electrodes connected to opposite sides of the first channel layer and to opposite sides of the second channel layer. A gate structure surrounds the first and second channel layers of each of the first and second transistors. The first transistor further includes a third channel layer below the second channel layer. In the first transistor, the gate structure is positioned at a same level as the third channel layer.

According to an exemplary embodiment of the present inventive concepts, a first transistor is disposed on an NMOS region of the substrate. A second transistor is disposed on a PMOS region of the substrate. The first transistor includes: a plurality of first channel layers stacked on the substrate; and a plurality of first source/drain electrodes connected to opposite sides of the first channel layers. The second transistor includes: a plurality of second channel layers stacked on the substrate; and a plurality of second source/drain electrodes connected to opposite sides of the second channel layers. The amount of the second channel layers is less than the amount of the first channel layers. A spacing distance between the substrate and an uppermost one of the first channel layers is the same as the spacing distance between the substrate and an uppermost one of the second channel layers.

According to an exemplary embodiment of the present inventive concepts, a method for manufacturing a semiconductor device includes forming an insulating layer on a substrate having a first region and a second region. First and second sacrificial layers and first and second preliminary channel layers are sequentially formed on the insulating layer. The first and second sacrificial layers and the first and second preliminary channel layers are removed from the second region of the substrate. An additional sacrificial layer is formed on the second region, the additional sacrificial layer having a top surface that has a same level as a top surface of the first preliminary channel layer or the second preliminary channel layer on the first region. At least one second additional sacrificial layer and at least one additional preliminary channel layer are sequentially stacked. The sacrificial layers and preliminary channel layers are patterned to form a first semiconductor structure on the first region and a second semiconductor structure on the second region. Each of the first and second semiconductor structures includes: a gate electrode disposed on the insulating layer; a plurality of channel layers that are surrounded by the gate electrode and stacked in a direction perpendicular to a top surface of the insulating layer; and a plurality of dielectric layers between the gate electrode and the channel layers. The amount of the channel layers provided in the first semiconductor structure is greater than the amount of the channel layers provided in the second semiconductor structure.

### BRIEF DESCRIPTION OF THE DRAWINGS

FIG. 1 illustrates a perspective view showing a transistor of a semiconductor device according to an exemplary embodiment of the present inventive concepts.

FIG. 2 illustrates a perspective view showing a semiconductor device according to an exemplary embodiment of the present inventive concepts.

FIGS. 3A and 3B illustrate cross-sectional views showing a semiconductor device respectively taken along lines A-A′, B-B′, and C-C′ of FIG. 2 according to exemplary embodiments of the present inventive concepts.

FIGS. 4A to 6A and 4B to 6B illustrate cross-sectional views showing a semiconductor device according to exemplary embodiments of the present inventive concepts.

FIGS. 7A to 14A and 7B to 14B illustrate cross-sectional views showing a method of fabricating a semiconductor device according to exemplary embodiments of the present inventive concepts.

FIGS. 15A and 15B illustrate cross-sectional views showing a method of fabricating a semiconductor device according to exemplary embodiments of the present inventive concepts.

FIG. 16 illustrates a circuit diagram of a semiconductor device according to exemplary embodiments of the present inventive concepts.

FIG. 17 illustrates a plan view showing a layout of the semiconductor device depicted in FIG. 16.

### DETAILED DESCRIPTION OF THE EXEMPLARY EMBODIMENTS

The following will now describe exemplary embodiments of a semiconductor device according to the present inventive concepts with reference to accompanying drawings.

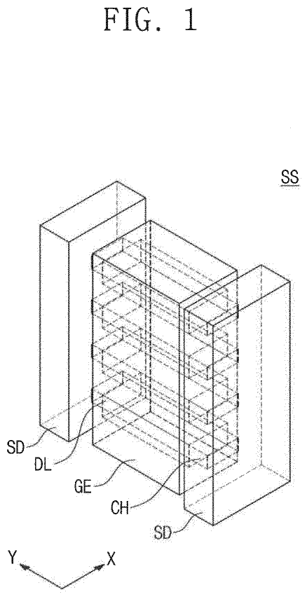

Referring to FIG. 1, a semiconductor structure SS may be provided. The semiconductor structure SS may include channel layers CH, a gate electrode GE, and source/drain electrodes SD.

The channel layers CH may be vertically spaced apart from each other. In an exemplary embodiment, the channel layers CH may be nano-sheets. For example, the channel layers CH may have a plate or bar shape extending in a second direction Y. The channel layers CH may serve as charge pathways between the source/drain electrodes SD. The channel layers CII may include silicon (Si).

The gate electrode GE may surround the channel layers CH. For example, in an exemplary embodiment, the gate electrode GE may cover the channel layers CH and expose lateral surfaces in the second direction Y of the channel layers CH. In such embodiment, the gate electrode GE may cover top surfaces, bottom surfaces, and lateral surfaces in a first direction X of the channel layers CH. Dielectric layers DL may electrically insulate the gate electrode GE from the channel layers CH.

The dielectric layers DL may be provided between the gate electrode GE and the channel layers CH. Each of the dielectric layers DL may be configured to electrically insulate a corresponding one of the channel layers CH from the gate electrode GE. In an exemplary embodiment, the dielectric layers DL, may include a high-k dielectric material.

The source/drain electrodes SD may be disposed on opposite sides of the Channel layers CH. For example, a source electrode may be connected to one side in the second direction Y of the channel layers CH, and a drain electrode may be connected to other side in the second direction Y of the channel layers CH The source/drain electrodes SD may be spaced apart and electrically insulated from the gate electrode GE.

The channel layers CH, the gate electrode GE, and the source/drain electrodes SD may constitute a metal oxide semiconductor (MOS) transistor.

According to exemplary embodiments of the present inventive concepts, a semiconductor device may have at least two of the transistors discussed with reference to FIG. 1. The following will describe an exemplary embodiment in which transistors share a single gate structure GS.

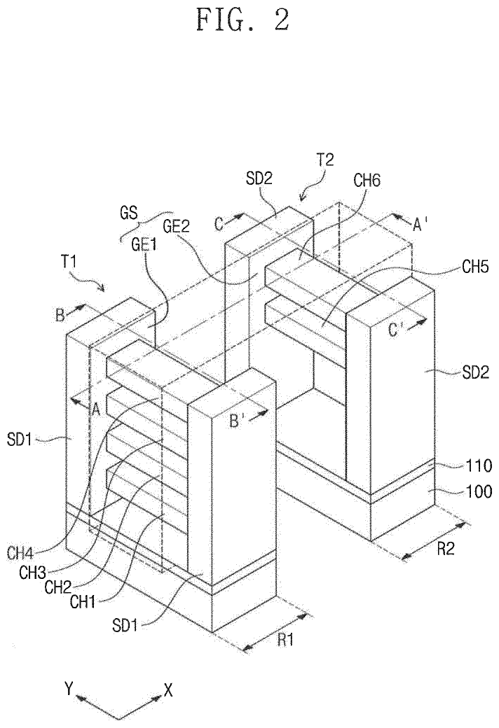

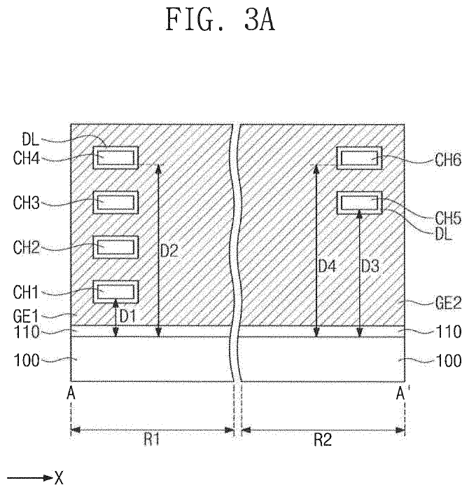

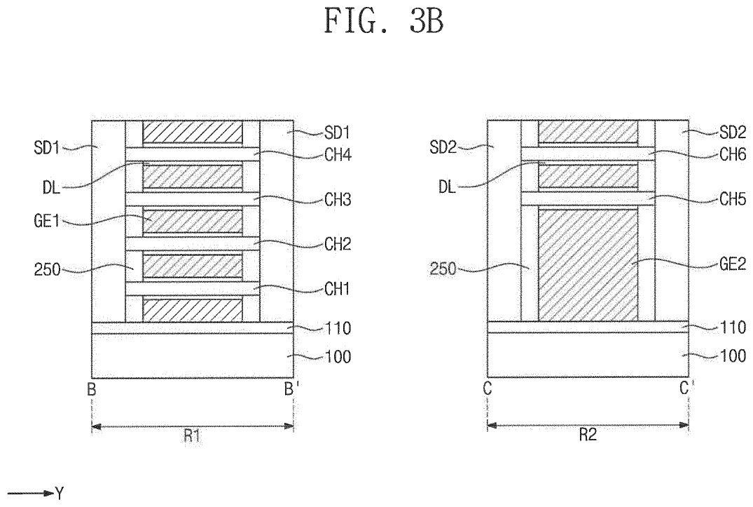

Referring to FIGS. 2, 3A, and 3B, a substrate 100 may be provided. The substrate 100 may have a first region R1 and a second region R2 which are spaced apart along the first direction X. For example, the first region R1 may be a negative channel metal oxide semiconductor (“NMOS”) area on which NMOS transistors are provided, and the second region R2 may be a positive channel metal oxide semiconductor (“PMOS”) area on which PMOS transistors are provided. The substrate 100 may include a semiconductor substrate. For example, the substrate 100 may be a bulk silicon substrate or a silicon-on-insulator (SOI) substrate.

An insulating layer 110 may be disposed on the substrate 100. The insulating layer 110 may cover the first and second regions R1 and R2 of the substrate 100. The insulating layer 110 may include silicon oxide (SiOx) or silicon nitride (SiNx).

The insulating layer 110 may be provided thereon with a first transistor T1 and a second transistor T2. The first transistor T1 may be disposed on the first region R1, and the second transistor T2 may be disposed on the second region R2. Each of the first and second transistors T1 and T2 may have an identical or similar structure to that discussed with reference to FIG. 1. For example, in the exemplary embodiment shown in FIG. 2, the first transistor T1 may include first, second, third, and fourth channel layers CH1, CH2, CH3, and CH4 spaced apart from each other on the insulating layer 110 of the first region R1. A first gate electrode GE1 may surround the first to fourth channel layers CH1 to CH4. First source/drain electrodes SD1 may be connected to the first to fourth channel layers CH1 to CH4. The first to fourth channel layers CH1 to CH4 may be sequentially stacked on the insulating layer 110. For example, the channel layers CH1 to CH4 may be stacked vertically in a direction perpendicular to the top surface of the insulating layer 110.

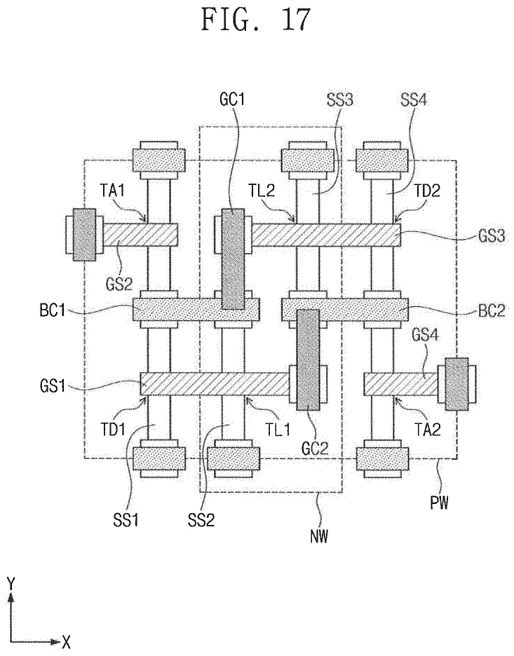

In the exemplary embodiment shown in FIG. 2, the second transistor 12 may include fifth and sixth channel layers CH5 and CH6 spaced apart from each other on the insulating layer 110 of the second region R2. A second gate electrode GE2 surrounds the fifth and sixth channel layers CH5 and CH6. Second source/drain electrodes SD2 are connected to the fifth and sixth channel layers CH5 and CH6. The fifth and sixth channel layers CH5 and CH6 may be sequentially stacked on the insulating layer 110. For example, the channel layers CH1 to CH4 may be stacked vertically in a direction perpendicular to the top surface of the insulating layer 110. The first gate electrode GE1 and the second gate electrode GE2 may be connected to each other to constitute a single gate structure (e.g., a first gate structure GS1 which will be discussed below with the reference to FIG. 17).

In an exemplary embodiment, the number of channel layers included in the first transistor T1 may be greater than the number of channel layers included in the second transistor T2. The exemplary embodiments shown in FIGS. 2, 3A, and 3B include the first transistor T1 having four channel layers CH1 to CH4, and the second transistor 12 having two channel layers CH5 and CH6. However, exemplary embodiments of the present inventive concepts are not limited thereto. The number of channel layers included in the first transistor T1 may be two or more, and the number of channel layers included in the second transistor T2 may be one or more. Because the first and second transistors T1 and T2 may have a different amount (e.g., number) of channel layers, an arrangement of the channel layers CH1 to CH4 included in the first transistor T1 may be different from the arrangement of the channel layers CH5 and CH6 included in the second transistor T2.

In an exemplary embodiment, each of the channel layers CH5 and CH6 included in the second transistor T2 may be located at the same level as the level of one of the channel layers CH1 to CH4 included in the first transistor T1. For example, in the exemplary embodiments shown in FIGS. 3A and 3B, the sixth channel layer CH6 may be located at the same level as the level of the fourth channel layer CH4, and the fifth channel layer CH5 may be located at the same level as the level of the third channel layer CH3. In this embodiment, a spacing distance D2 between the fourth channel layer CH4 and a top surface of the substrate 100 may be the same as a spacing distance D4 between the sixth channel layer CH6 and the top surface of the substrate 100. A spacing distance D1 between the first channel layer CH1 and the top surface of the substrate 100 may be less than a spacing distance D3 between the fifth channel layer CH5 and the top surface of the substrate 100. In the second transistor T2, the second gate electrode GE2 may occupy locations at the same level as those of the first and second channel layers CH1 and CH2.

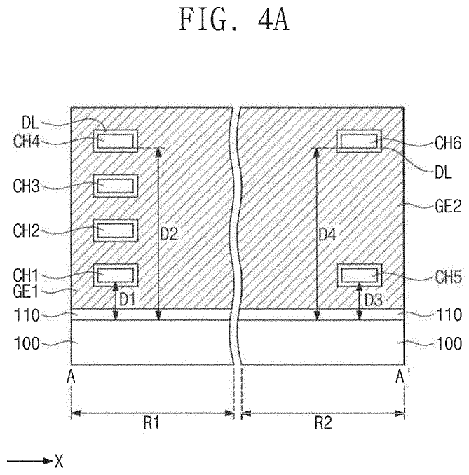

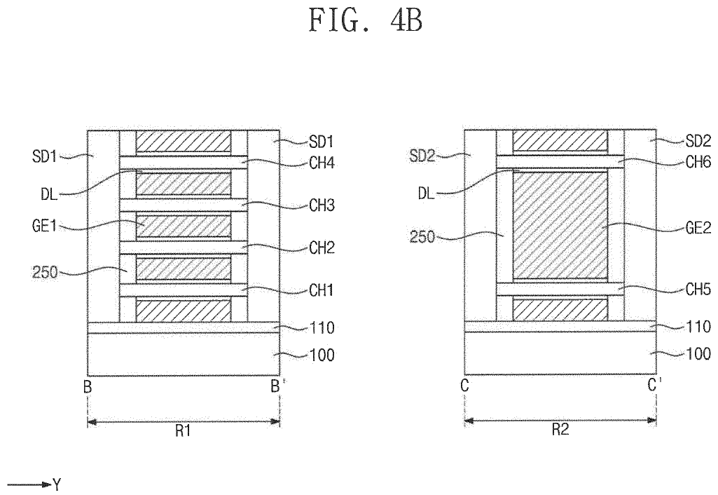

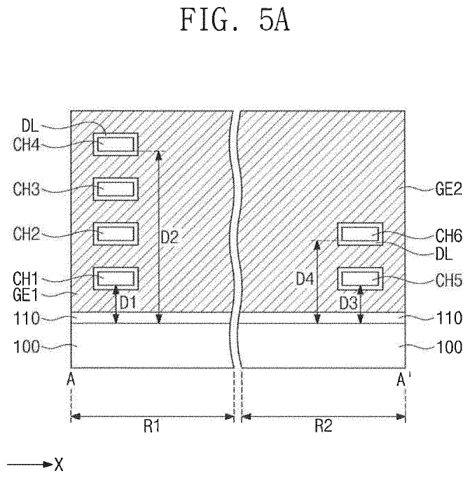

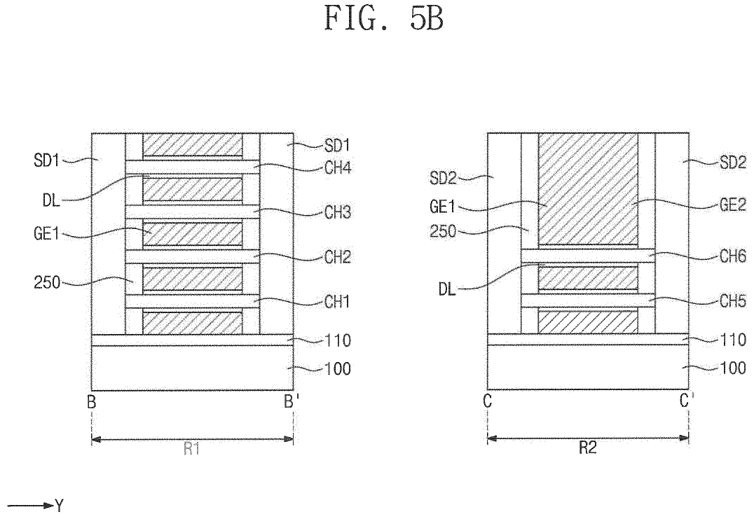

In another exemplary embodiment shown in FIGS. 4A and 4B, the sixth channel layer CH6 may be located at the same level as the level off the fourth channel layer CH4. The fifth channel layer CH5 may be located at the same level as the level of the first channel layer CH1. In this embodiment, the spacing distance D2 between the fourth channel layer CH4 and the top surface of the substrate 100 may be the same as the spacing distance D4 between the sixth channel layer CH6 and the top surface of the substrate 100. The spacing distance D1 between the first channel layer CH1 and the top surface of the substrate 100 may be the same as the spacing distance D3 between the fifth channel layer CH5 and the top surface of the substrate 100. As shown in FIG. 4B, in the second transistor T2, the second gate electrode GE2 may be positioned at the same level as the positions of the second and third channel layers CH2 and CH3 of the first transistor T1.

In another exemplary embodiment, shown in FIGS. 5A and 5B, the sixth channel layer CH6 may be located at the same level as the level of the second channel layer CH1. The fifth channel layer CH5 may be located at the same level as the level of the first channel layer CH1. In this embodiment, the spacing distance D2 between the fourth channel layer CH4 and the top surface of the substrate 100 may be greater than the spacing distance D4 between the sixth channel layer CH6 and the top surface of the substrate 100. The spacing distance D1 between the first channel layer CH1 and the top surface of the substrate 100 may be the same as the spacing distance D3 between the fifth channel layer CH5 and the top surface of the substrate 100. In the second transistor T2, the second gate electrode GE2 may occupy locations at the same level as those of the third and fourth channel layers CH3 and CH4.

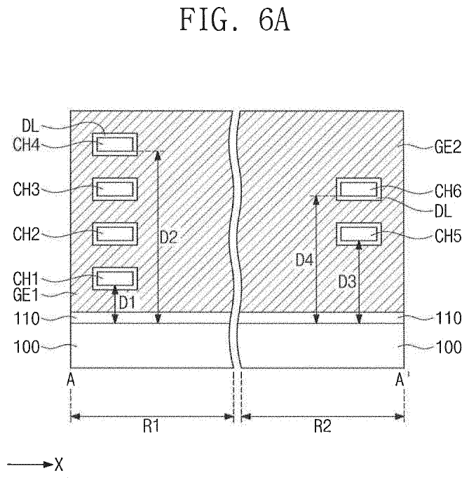

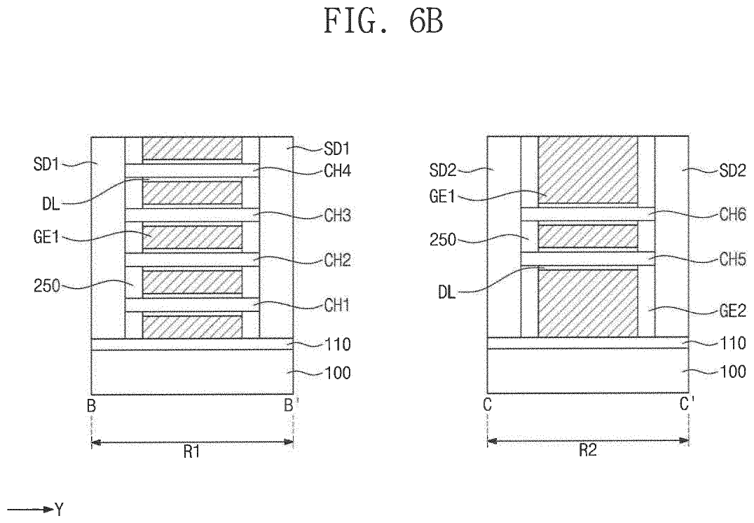

In another exemplary embodiment shown in FIGS. 6A and 6B, the sixth channel layer CH6 may be located at the same level as the level of the third channel layer CH3, and the fifth channel layer CH5 may be located at the same level as the level of the second channel layer CH2. It this embodiment, the spacing distance 132 between the fourth channel layer CH4 and the top surface of the substrate 100 may be greater than the spacing distance D4 between the sixth channel layer CH6 and the top surface of the substrate 100. The spacing distance D1 between the first channel layer CH1 and the top surface of the substrate 100 may be less than the spacing distance D3 between the fifth channel layer CH5 and the top surface of the substrate 100. In the second transistor T2, the second gate electrode GE2 may be positioned at the same level as the positions of the first and fourth channel layers CH1 and CH4.

As discussed above, the amount of channel layers included in the second transistor T2 may be less than the amount of channel layers included in the first transistor T1, and each of channel layers included in the second transistor T2 may be located at a level corresponding to the level of one of channel layers included in the first transistor T1. The arrangements of channel layers included in the second transistor T2 are not limited to the exemplary embodiments discussed above, and may be variously changed based on the number and configuration of channel layers included in each of the first and second transistors T1 and T2.

In certain exemplary embodiments, the first and second transistors T1 and T2 may be configured to have different amounts of channel layers, and thus a semiconductor device may improve in electrical characteristics. For example, in an exemplary embodiment in which a semiconductor device is configured using CMOS cells, when the amount of channel layers included in the NMOS transistors is greater than the amount of channel layers included in the PMOS transistors, the semiconductor device may improve in write operating characteristics. In addition, various transistors of the semiconductor device may be designed to have different electrical characteristics.

In the first transistor T1, the first gate electrode GE1 may surround the first to fourth channel layers CH1 to CH4. For example, the first gate electrode GE1 may encapsulate the first to fourth channel layers CH1 to CH4. In the second transistor T2, the second gate electrode GE2 may surround the fifth and sixth channel layers CH5 and CH6. For example, the second gate electrode GE2 may encapsulate the fifth and sixth channel layers CH5 and CH6. The first and second gate electrodes GE1 and GE2 may extend in the first direction X and may be connected to each other to form a single gate structure GS. For example, in an exemplary embodiment, the gate structure GS may be a common gate electrode of the first and second transistors T1 and T2.

Dielectric layers DL may be provided between the gate electrodes GE1 and GE2 and the channel layers CH1 to CH6. The dielectric layers DL may be configured to electrically insulate the channel layers CH1 to CH6 front the gate electrodes GE1 and GE2. The dielectric layers DL may include a high-k dielectric material.

The first source/drain electrodes SD1 may be disposed on opposite sides in the second direction Y of the first to fourth channel layers CH1 to CH4. The second source/drain electrodes SD2 may be disposed on opposite sides in the second direction Y of the fifth and sixth channel layers CH5 and CH6. The first source/drain electrodes SD1 may be connected to the first to fourth channel layers CH1 to CH4. The second source/drain electrodes SD2 may be connected to the fifth and sixth channel layers CH5 and CH6.

First spacer patterns 250 may be provided between the first gate electrode GE1 and the first source/drain electrodes SD1 and between the second gate electrode GE2 and the second source/drain electrodes SD2. The first spacer patterns 250 may be provided on at least one side of the first gate electrode GE1 and on at least one side of the second gate electrode GE2.

Each of the first source/drain electrodes SD1 and the first gate electrode GE1 may be spaced apart from each other across the first spacer patterns 250. Each of the second source/drain electrodes SD2 and the second gate electrode GE2 may be spaced apart from each other across the first spacer patterns 250. The first spacer patterns 250 may be configured to electrically insulate the source/drain electrodes SD1 and the second source/drain electrodes SD2 from the first gate electrode GE1 and the second gate electrodes GE2, respectively.

As discussed above, an exemplary embodiment is explained in which the amount of channel layers on the first region R1 (e.g., the NMOS area) is greater than the amount of channel layers on the second region R2 (e.g., the PMOS area). However, exemplary embodiments of the present inventive concepts are not limited thereto. In other exemplary embodiments, the second transistor T2 on the second region R2 may include an amount of channel layers that is greater than the amount of channel layers included in the first transistor T1 on the first region R1. Alternatively, in consideration of electrical Characteristics, transistors of a semiconductor device according to exemplary embodiments of the present inventive concepts may have different numbers of channel layers regardless of a region on which the transistors are formed.

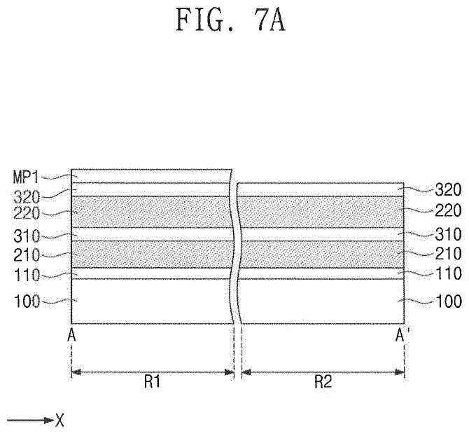

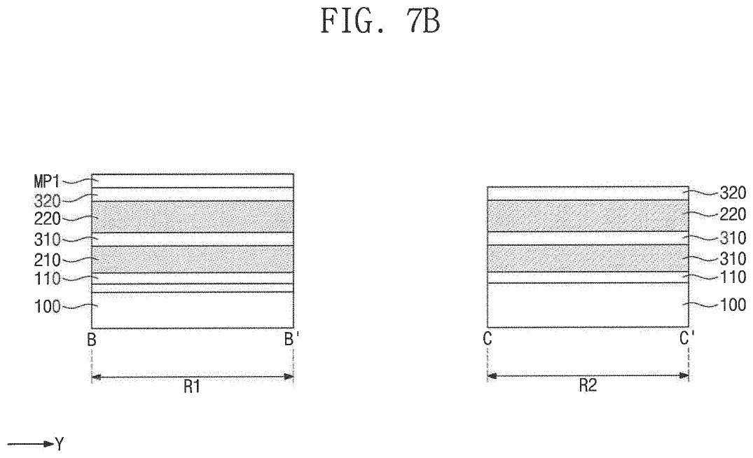

FIGS. 7A to 14A illustrate cross-sectional views taken along an X-direction of FIG. 2, showing a method of fabricating a semiconductor device according to exemplary embodiments of the present inventive concepts. FIGS. 7B to 14B illustrate cross-sectional views taken along a Y-direction of FIG. 2, showing a method of fabricating a semiconductor device according to exemplary embodiments of the present inventive concepts. The following will now describe an exemplary embodiment of a method of fabricating the semiconductor device shown in FIGS. 2, 3A, and 3B.

Referring to FIGS. 7A and 7B, a substrate 100 may be provided. The substrate 100 may include a semiconductor substrate. For example, in an exemplary embodiment, the semiconductor substrate may be a bulk silicon substrate or a silicon-on-insulator (SOI) substrate. The substrate 100 may have a first region R1 on which a first transistor (see T1 of FIG. 2) may be formed and a second region R2 on which a second transistor (see T2 of FIG. 2) may be formed.

An insulating layer 110 may be formed on the substrate 100. The insulating layer 110 may be formed by performing an oxidation process or a nitridation process on an upper portion of the substrate 100. Alternatively, the insulating layer 110 may be formed by depositing a dielectric material on a top surface of the substrate 100. The insulating layer 110 may include silicon oxide (SiOx) or silicon nitride (SiNx).

In an exemplary embodiment, a first sacrificial layer 210, a first preliminary channel layer 310, a second sacrificial layer 220, and a second preliminary channel layer 320 may be sequentially formed on the substrate 100. The first preliminary channel layer 310 and the second preliminary channel layer 320 may be formed by an epitaxial growth process or a molecular beam epitaxy process. The first sacrificial layer 210 and the second sacrificial layer 220 may be formed by the same process as that used fir forming the first preliminary channel layer 310 and the second preliminary channel layer 320. The first sacrificial layer 210, the first preliminary channel layer 310, the second sacrificial layer 220, and the second preliminary channel layer 320 may be successively formed in-situ. The first preliminary channel layer 310 and the second preliminary channel layer 320 may include silicon (Si) or a III-V group semiconductor. The sacrificial layers 210 and 220 and the preliminary channel layers 310 and 320 may each have a thickness in a direction perpendicular to the top surface of the substrate 100. In an exemplary embodiment, each of the sacrificial layers 210 and 220 may have a thickness ranging from about 1 Å to about 100 nm. Each of the preliminary channel layers 310 and 320 may have a thickness ranging from about 1 Å to about 100 nm. The first and second sacrificial layers 210 and 220 may include a material having an etch selectivity with respect to the first and second preliminary channel layers 310 and 320. For example, in an exemplary embodiment, the first and second sacrificial layers 210 and 220 may include silicon oxide (SiOx), silicon nitride (SiNx), silicon-germanium (SiGe), or silicon-germanium (SiGe) doped with aluminum (Al).

A first mask pattern MP1 may be formed on the second preliminary channel layer 320. The first mask pattern MP1 may cover the second preliminary channel layer 320 on the first region R1 of the substrate 100. The first mask pattern MP1 may not be formed on the second region R2 of the substrate 100 thereby exposing a top surface of the second preliminary channel layer 320 on the second region R2 of the substrate 100.

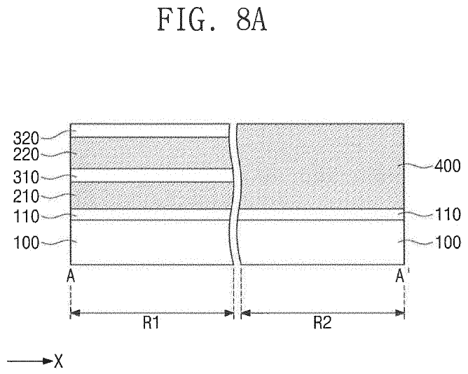

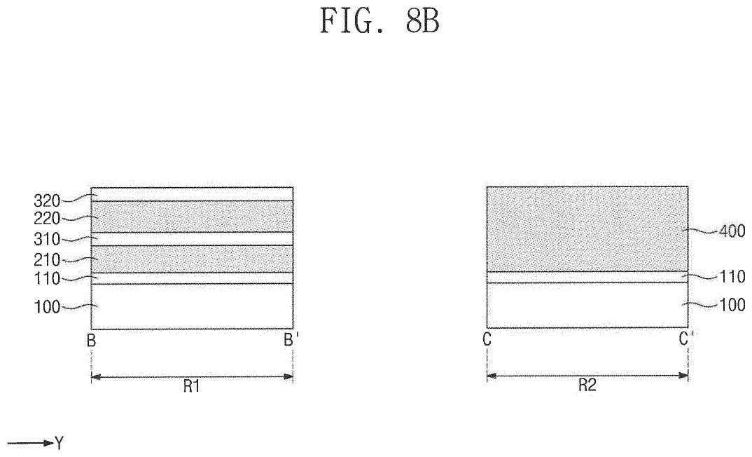

Referring to FIGS. 8A and 8B, a patterning process may be performed on the first sacrificial layer 210, the first preliminary channel layer 310, the second sacrificial layer 220, and the second preliminary channel layer 320. For example, the first mask pattern MP1 may be used as an etching mask to remove the first sacrificial layer 210, the first preliminary channel layer 310, the second sacrificial layer 220, and the second preliminary channel layer 320 from the second region R2. The first sacrificial layer 210, the first preliminary channel layer 310, the second sacrificial layer 220, and the second preliminary channel layer 320 may remain on the first region R1. The first mask pattern W may be subsequently removed.

An additional sacrificial layer 400 may be formed on the insulating layer 110 of the second region R2. The additional sacrificial layer 400 may be formed to have a top surface at the same level as that of the top surface of the second preliminary channel layer 320.

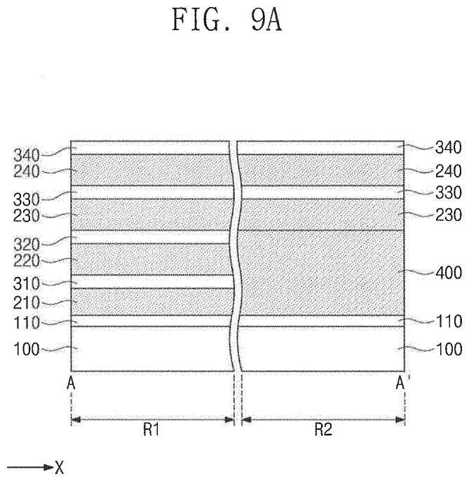

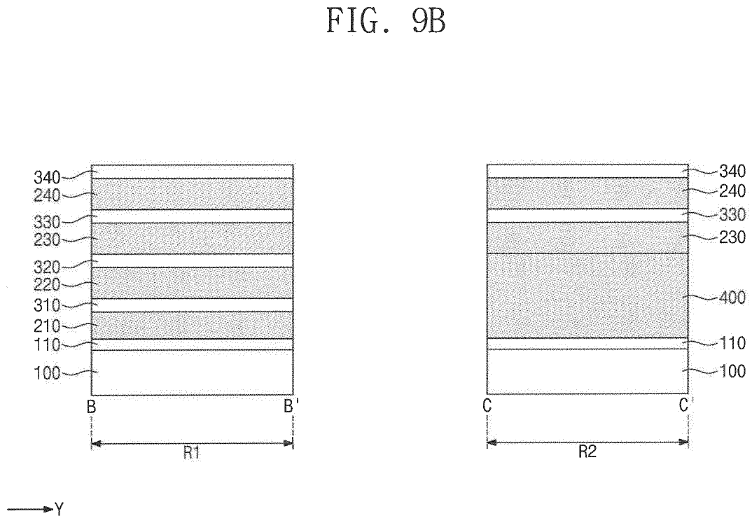

Referring to FIGS. 9A and 9B, a third sacrificial layer 230, a third preliminary channel layer 330, a fourth sacrificial layer 240, and a fourth preliminary channel layer 340 may be sequentially stacked on the substrate 100. For example, the third sacrificial layer 230 may be formed on the second preliminary channel layer 320 of the first region R1 and on the additional sacrificial layer 400 of the second region R2, and thereafter the third preliminary channel layer 330, the fourth sacrificial layer 240, and the fourth preliminary channel layer 340 may be successively formed. The third and fourth preliminary channel layers 330 and 340 may be formed by an epitaxial growth process or a molecular beam epitaxy process. In an exemplary embodiment, the third and fourth sacrificial layers 230 and 240 may be formed by the same process as the process used for forming the third and fourth preliminary channel layers 330 and 340. The third sacrificial layer 230, the third preliminary channel layer 330, the fourth sacrificial layer 240, and the fourth preliminary channel layer 340 may be successively formed in-situ. The third and fourth preliminary channel layers 330 and 340 may include the same material as the first and second preliminary channel layers 310 and 320. Since the additional sacrificial layer 400 and the second preliminary channel layer 320 may be formed to have their top surfaces at the same level, the third sacrificial layer 230, the third preliminary channel layer 330, the fourth sacrificial layer 240, and the fourth preliminary channel layer 340 may be formed to have their flat shapes. Therefore, the first to fourth preliminary channel layers 310 to 340 may be provided on the first region R1, and the third and fourth preliminary channel layers 330 and 340 may be provided on the second region R2.

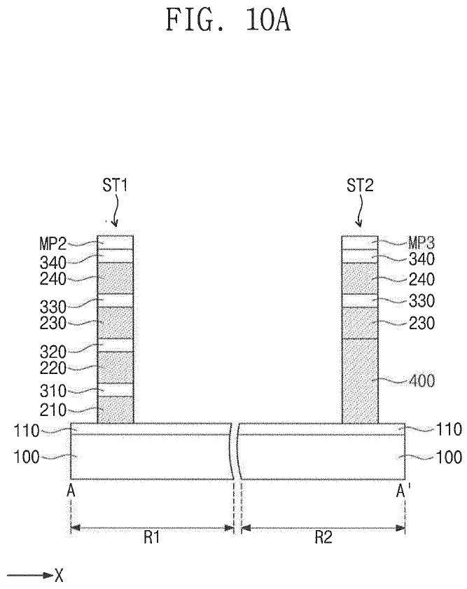

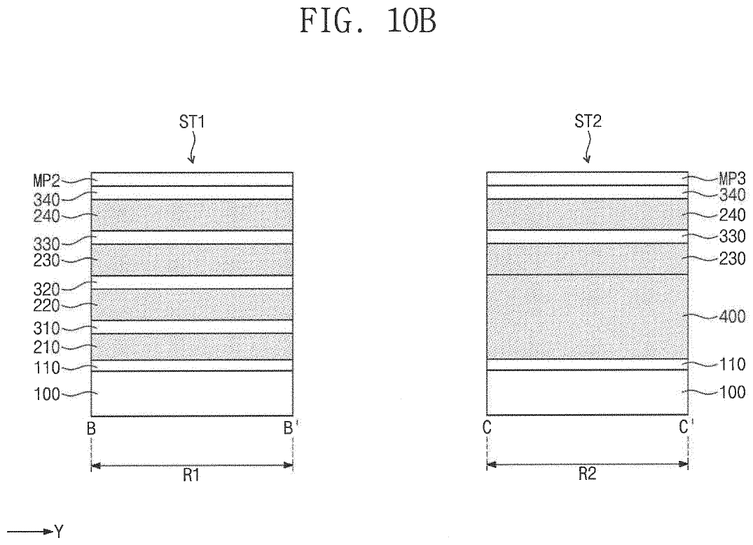

Referring to FIGS. 10A and 10B, a patterning process may be performed on the first to fourth sacrificial layers 210 to 240 and the first to fourth preliminary channel layers 310 to 340. For example, in an exemplary embodiment, a second mask pattern MP2 and a third mask pattern MP3 may be formed on the fourth preliminary channel layer 340. The second mask pattern MP2 may be formed on the first region R1, and the third mask pattern MP3 may be formed on the second region R2. The second and third mask patterns MP2 and MP3 may extend in a second direction Y. An etching process may be performed in which the second and third mask patterns MP2 and MP3 are used as an etching mask to etch the first to fourth sacrificial layers 210 to 240, the additional sacrificial layer 400, and the first to fourth preliminary channel layers 310 to 340. The result of the etching process is the formation of a first structure ST1 on the first region R1 and a second structure ST2 may be formed on the second region R2.

In other exemplary embodiments of the present principles, the etching process may also etch the substrate 100 and the insulating layer 110, in this embodiment, an upper portion of the substrate 100 may be etched to form a base channel layer (not shown) below the first sacrificial layer 210. Device isolation patterns (not shown) may be formed to fill one side of the base channel layer (not shown). The formation of the device isolation patterns (not shown) may include forming a dielectric layer on the substrate 100 to fill a gap between a plurality of the base channel layers (not shown) and recessing the dielectric layer to completely expose lateral surfaces of the first structure ST1 and lateral surfaces of the second structure ST2. The device isolation patterns may have their top surfaces at a lower level than that of a top surface of the base channel layer. In an exemplary embodiment, the device isolation patterns may include oxide, nitride, or oxynitride.

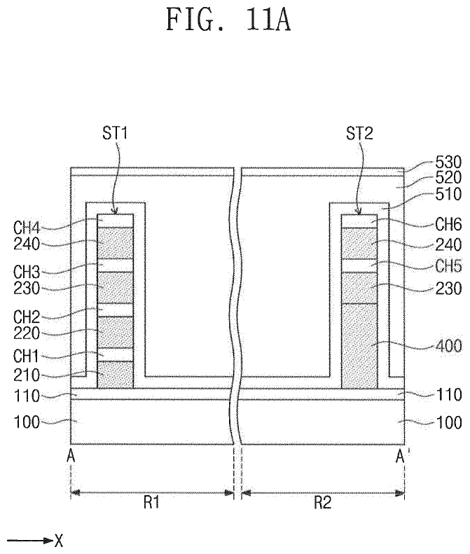

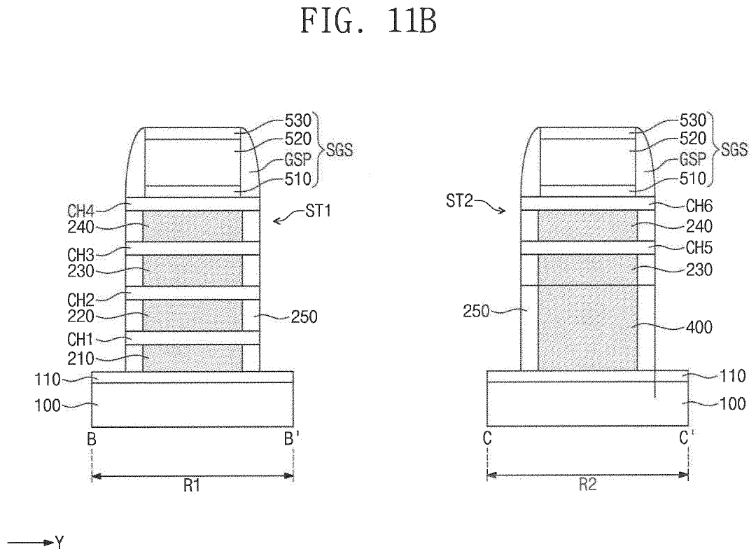

Referring to FIGS. 11A and 11B, the second and third mask patterns MP2 and MP3 may be removed, and thereafter a sacrificial gate structure SGS may be formed. The sacrificial gate structure SGS may extend in a first direction X and run across the first and second structures ST1 and ST2. The sacrificial gate structures SGS may include an etch stop pattern 510, a sacrificial gate pattern 520, and a mask pattern 530 that may be sequentially stacked on the substrate 100. The sacrificial gate pattern 520 may have a linear shape extending in the first direction X. The sacrificial gate pattern 520 may cover facing lateral surfaces in the first direction X of the first and second structures ST1 and ST2, and also cover top surfaces of the first and second structures ST1 and ST2. The etch stop pattern 510 may be interposed between the sacrificial gate pattern 520 and the first structure ST1 and between the sacrificial gate pattern 520 and the second structure ST2. The formation of the sacrificial gate pattern 520 and the etch stop pattern 510 may include sequentially forming on the substrate 100 an etch stop layer (not shown) and a sacrificial gate layer (not shown) that cover the first structure ST1 and the second structure ST2, forming on the sacrificial gate layer the mask pattern 530 that defines an area where the sacrificial gate pattern 520 is formed, and using the mask pattern 530 as an etching mask to sequentially pattern the sacrificial gate layer and the etch stop layer. In an exemplary embodiment, the etch stop layer may include a silicon oxide layer. The sacrificial gate layer may include a material having an etch selectivity with respect to the etch stop layer. The sacrificial gate layer may include, for example, polysilicon. The mask pattern 530 may be used as an etching mask to pattern the sacrificial gate layer to form the sacrificial gate pattern 520. The patterning of the sacrificial gate layer may include performing an etching process that has an etch selectivity with respect to the etch stop layer. After the sacrificial gate pattern 520 is formed, the etch stop layer may be removed from opposite sides of the sacrificial gate pattern 520 such that the etch stop pattern 510 may be locally formed below the sacrificial gate pattern 520.

The sacrificial gate structure SGS may further include gate spacers GSP din opposite sides of the sacrificial gate pattern 520. The formation of the gate spacers GSP may include forming on the substrate 100 a gate spacer layer (not shown) to cover the mask pattern 530, the sacrificial gate pattern 520, and the etch stop pattern 510, and then anisotropically etching the gate spacer layer. The mask pattern 530 and the gate spacers GSP may include, for example, silicon nitride.

After that, a patterning process may be performed to pattern the first and second structures ST1 and ST2. In this exemplary embodiment, portions of the first and second structures ST1 and ST2 may be removed from opposite sides of the sacrificial gate structure SGS. The removal of the portions of the first and second structures ST1 and ST2 may include using the mask pattern 530 and the gate spacers GSP as an etching mask to etch the portions of the first and second structures ST1 and ST2.

After the patterning process is performed, the first structure ST1 on the first region R1 may have first, second, third, and fourth channel layers CH1, CH2, CH3, and CH4 that are formed by patterning the first, second, third, and fourth preliminary channel layers 310, 320, 330, and 340. The second structure ST2 on the second region R2 may have fifth and sixth channel layers CH5 and CH6 that are formed by patterning the third and fourth preliminary channel layers 330 and 340. The first, second, third, and fourth channel layers CH1, CH2, CH3, and CH4 may serve as channels of a first transistor (see T1 of FIG. 2) that is formed on the first region R1, and the fifth and sixth channel layers CH3 and CH6 may serve as channels of a second transistor (see T2 of FIG. 2) that is formed on the second region R2. Therefore, the number of channel layers formed on the first region R1 may be different from that of channel layers formed on the second region R2.

According to some exemplary embodiments of the present inventive concepts, simple processes such as deposition and etching may be employed to form transistors having different numbers of channel layers.

The sacrificial gate structure SGS may cover the lateral surfaces of the first and second structures ST1 and ST2 in the first direction X. For example, the sacrificial gate pattern 520 may cover the top surfaces and the lateral surfaces in the first direction X of the first and second structures ST1 and ST2. The etch stop pattern 510 may be interposed between the sacrificial gate pattern 520 and the first structure ST1 and between the sacrificial gate pattern 520 and the second structure ST2. The first and second structures ST1 and ST2 may have their lateral surfaces in the second direction Y that are exposed without being covered with the sacrificial gate structure SGS.

An oxidation process may be performed on the substrate 100. The oxidation process may oxidize the lateral surfaces in the second direction of the first and second structures ST1 and ST2. Thus, first spacer patterns 250 may be formed on opposite sides of each of the sacrificial layers 210, 220, 230, 240, and 400. The first spacer patterns 250 may be spaced apart in the second direction Y from each other across a corresponding one of the sacrificial layers 210, 220, 230, 240, and 400. The first spacer patterns 250 may be oxidized portions of each of the sacrificial layers 210, 220, 230, 240, and 400. For example, when the sacrificial layers 210, 220, 230, 240, and 400 include silicon-germanium (SiGe) doped with aluminum (Al), the first spacer patterns 250 may include aluminum oxide (e.g., Al₂O₃).

During the oxidation process, lateral surfaces of the channel layers CH1 to CH6 may be oxidized to form second spacer patterns (not shown). The second spacer patterns may be subsequently removed.

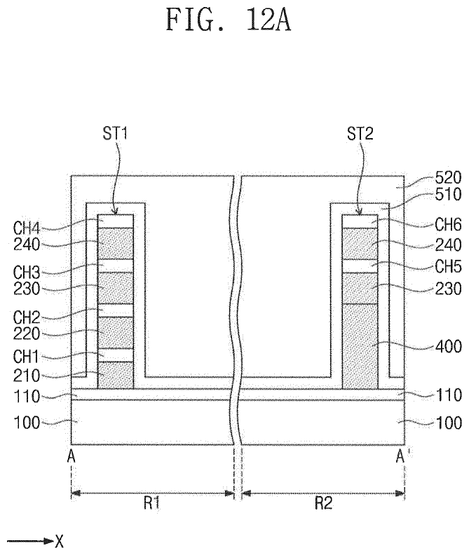

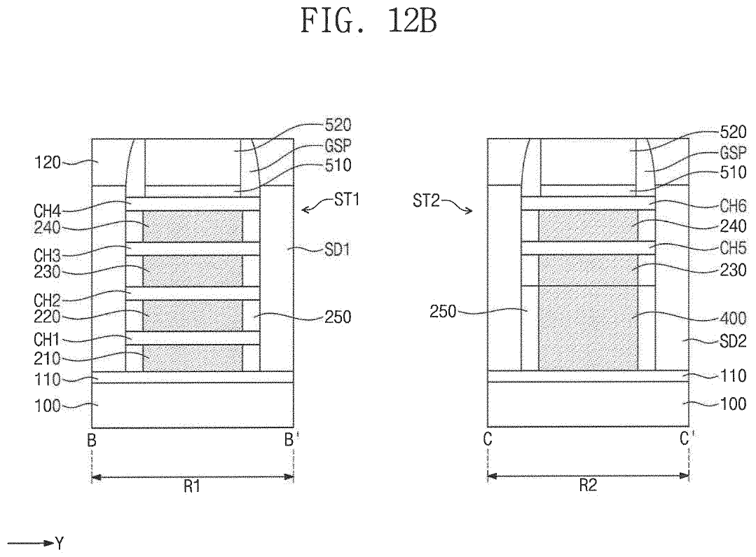

Referring to FIGS. 12A and 12B, first source/drain electrodes SD1 and second source/drain electrodes SD2 may be formed. For example, the first source/drain electrodes SD1 may be formed on lateral surfaces in the second direction Y of the first to fourth channel layers CH1 to CH4. The second source/drain electrodes SD2 may be formed on lateral surfaces in the second direction Y of the fifth and sixth channel layers CH5 and CH6. A selective epitaxial growth (SEG) process may be used to form the first and second source/drain electrodes SD1 and SD2 on exposed lateral surfaces of the first to sixth channel layers CH1 to CH6. The first and second source/drain electrodes SD1 and SD2 may include one or more of silicon-germanium (SiGe), silicon (Si), and silicon carbide (SiC). The first and second source/drain electrodes SD1 and SD2 may include single crystalline silicon or polysilicon. The first source/drain electrodes SD1 may be electrically connected to each other through the first to fourth channel layers CH1 to CH4, and the second source/drain electrodes SD2 may be electrically connected to each other through the fifth and sixth channel layers CH5 and CH6. Each of the first and second source/drain electrodes SD1 and SD2 and each of the sacrificial layers 210, 220, 230, 240, and 400 may be spaced apart from each other across the first spacer pattern 250. The first and second source/drain electrodes SD1 and SD2 may correspondingly contact the first spacer patterns 250.

An interlayer dielectric layer 120 may be formed on the substrate 100 on which the first and second source/drain electrodes SD1 and SD2 are formed. The formation of the interlayer dielectric layer 120 may include forming on the substrate 100 a dielectric layer to cover the first and second source/drain electrodes SD1 and SD2 and the sacrificial gate structure SGS. A planarization process may then be performed on the dielectric layer until the sacrificial gate pattern 520 is exposed. The planarization process may remove the mask pattern 530. In exemplary embodiments, the interlayer dielectric layer 120 may include one or more of a silicon oxide layer, a silicon nitride layer, a silicon oxynitride layer, and a low-k dielectric layer.

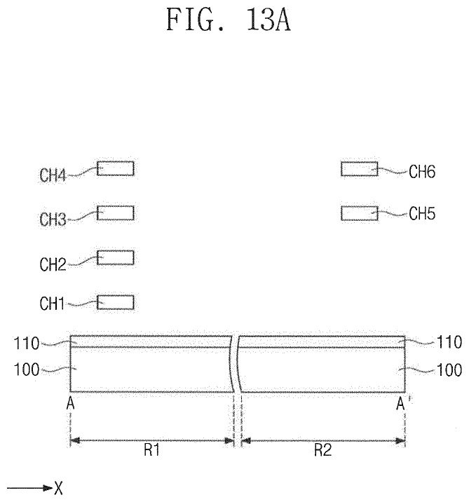

Referring to FIGS. 13A and 13B, the sacrificial gate pattern 520 and the etch stop pattern 510 may be removed. For example, in an exemplary embodiment, the sacrificial gate pattern 520 may be etched by performing an etching process that has an etch selectivity with respect to the gate spacer GSP, the interlayer dielectric layer 120, and the etch stop pattern 510. The etch stop pattern 510 may then be removed to expose the first and second structures ST1 and ST2. Therefore, the channel layers CH1 to CH6 and the sacrificial layers 210, 220, 230, 240, and 400 may be exposed.

The sacrificial layers 210, 220 230, 240, and 400 may be removed. For example, in one exemplary embodiment, a wet etching process may be performed to selectively etch the sacrificial layers 210, 220, 230, 240, and 400. For example, when the sacrificial layers 210, 220, 230, 240, and 400 include silicon-germanium (SiGe) doped with dopants, and when the channel layers CH1 to CH6 include silicon (Si), the sacrificial layers 210, 220, 230, 240, and 400 may be selectively removed by a wet etching process in which peracetic acid is used as an etching source.

The removal of the sacrificial layers 210, 220, 230, 240, and 400 may result in the separation of the first to fourth channel layers CH1 to CH4 from each other, and also the separation of the fifth and sixth channel layers CH5 and CH6 from each other.

A doping process or an annealing process may also be performed on the first to sixth channel layers CH1 to CH6, For example, the first to fourth channel layers CH1 to CH4 may be doped with N-type dopants, and the fifth and sixth channel layers CH5 and CH6 may be doped with P-type dopants.

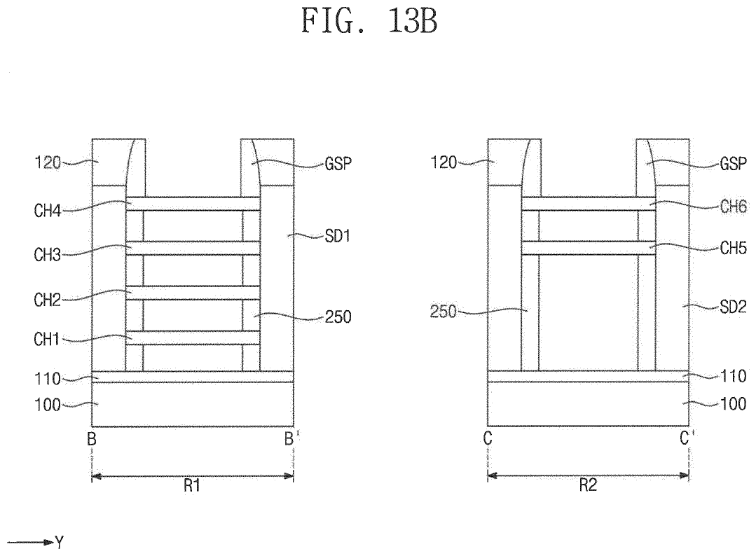

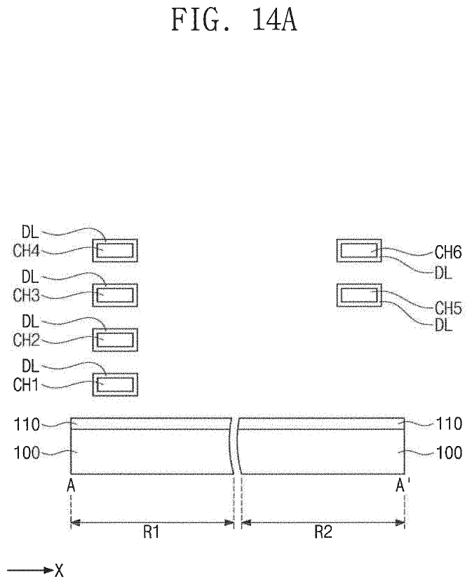

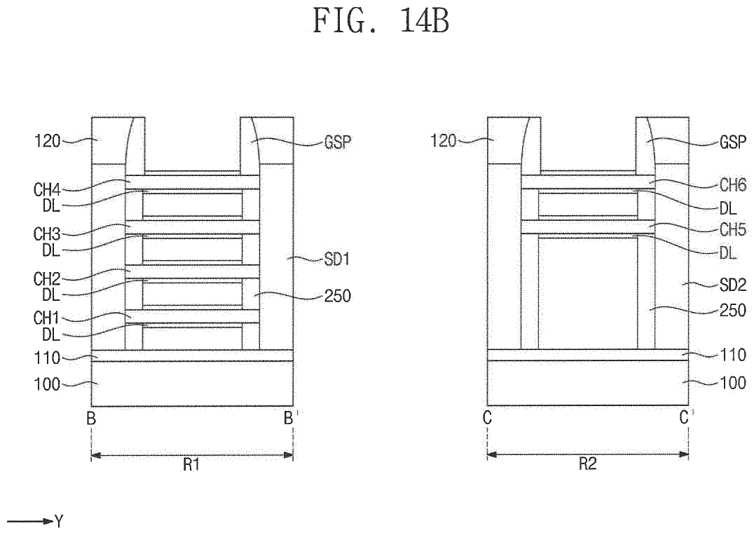

Referring to the exemplary embodiments shown in FIGS. 14A and 14B, dielectric layers D1, may be formed on surfaces of the first to sixth channel layers CH1 to CH6. For example, exposed surfaces of the first to sixth channel layers CH1 to CH6 may be deposited thereon with a high-k dielectric material to form the dielectric layers DL. An atomic layer deposition (ALD) process may be used to form the dielectric layers DL. Each of the dielectric layers DL may be formed to surround a corresponding one of the first to sixth channel layers CH1 to CH6. For example, the dielectric layers DL may be formed to cover top surfaces, bottom surfaces, and lateral surfaces in the first direction X of the first to sixth channel layers CH1 to CH6.

Alternatively, the dielectric layers DL may be formed by performing an oxidation process or a nitridation process on the surfaces of the first to sixth channel layers CH1 to CH6.

Referring hack to the exemplary embodiments shown in FIGS. 2, 3A, and 3B, a gate structure GS may be formed. For example, the formation of the gate structure GS may include forming a gate dielectric layer to conformally cover inner surfaces of spaces between the gate spacers GSP. A planarization process may then be performed until the interlayer dielectric layer 120 is exposed to locally form gate dielectric patterns (not shown) and gate electrodes GE1 and GE2 between the gate spacers GSP and between the channel layers CH1 to CH6. The gate electrodes GE1 and GE2 and the channel layers CH1 to CH6 may be spaced apart from each other across the gate dielectric patterns and the dielectric layers DL. The gate electrodes GE1 and GE2 and the first and second source/drain electrodes SD1 and SD2 may be spaced apart from each other across the first spacer patterns 250.

The above-mentioned processes may fabricate a semiconductor device of FIG. 2.

FIGS. 7A to 14A are referred to explain exemplary embodiments in which the second transistor (see T2 of FIG. 2) is formed to have two upper channel layers. However, exemplary embodiments of the present inventive concepts are not limited thereto. According to exemplary embodiments of the present inventive concepts, when the preliminary channel layers 310, 320, 330, and 340 and the sacrificial layers 210, 220, 230, 240 are stacked, a process may be performed to selectively remove from the second region R2 one or more of the preliminary channel layers 310 to 340 and one or more of the sacrificial layers 210 to 240.

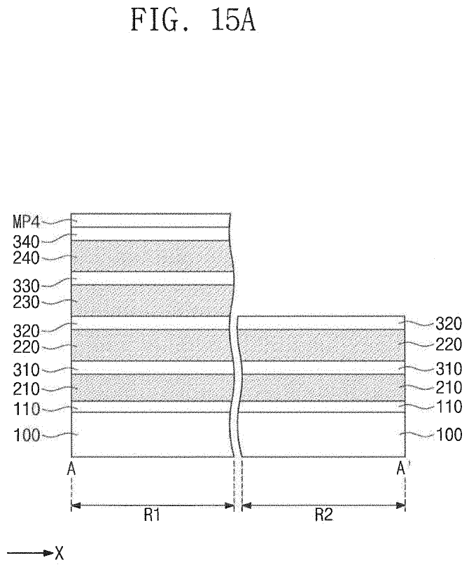

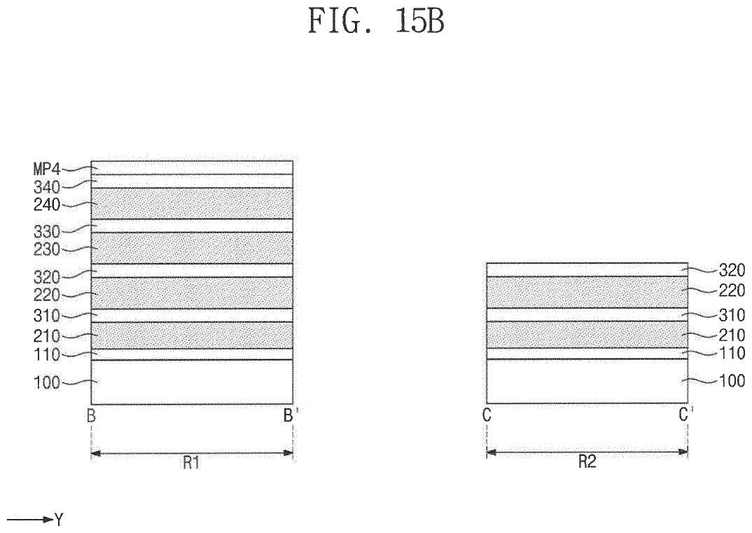

FIGS. 15A and 15B illustrate cross-sectional views showing a method of fabricating a semiconductor device according to some exemplary embodiments of the present inventive concepts.

Referring to FIGS. 15A and 15B, the insulating layer 110 may be sequentially stacked thereon with the first sacrificial layer 210, the first preliminary channel layer 310, the second sacrificial layer 220, the second preliminary channel layer 320, the third sacrificial layer 230, the third preliminary channel layer 330, the fourth sacrificial layer 240, and the fourth preliminary channel layer 340. In an exemplary embodiment, an epitaxial growth process or a molecular beam epitaxy process may be performed to form the first to fourth preliminary channel layers 310 to 340 and the first to fourth sacrificial layers 210 to 240.

A fourth mask pattern MP4 may be formed on the fourth preliminary channel layer 340. The fourth mask pattern MP4 may cover the fourth preliminary channel layer 340 on the first region R1 of the substrate 100. The fourth mask pattern MP4 may expose a top surface of the fourth preliminary channel layer 340 on the second region R2 of the substrate 100.

A patterning process may be performed on the third sacrificial layer 230, the third preliminary channel layer 330, the fourth sacrificial layer 240, and the fourth preliminary channel layer 340. For example, the fourth mask pattern MP4 may be used as an etching mask to remove the third sacrificial layer 230, the third preliminary channel layer 330, the fourth sacrificial layer 240, and the fourth preliminary channel layer 340 from the second region R2. The third sacrificial layer 230, the third preliminary channel layer 330, the fourth sacrificial layer 240, and the fourth preliminary channel layer 340 may remain on the first region R1. Therefore, the first to fourth preliminary channel layers 310 to 340 may be provided on the first region R1, and the first and second preliminary channel layers 310 and 320 may be provided on the second region R2.

The fourth mask pattern MP4 may be removed from a resultant structure of FIGS. 15A and 15B, and thereafter the processes discussed with reference to FIGS. 10A to 14A may be performed to fabricate a semiconductor device of FIGS. 5A and 5B.

Alternatively, the insulating layer 110 may be stacked thereon with the first sacrificial layer 210, the first preliminary channel layer 310, the second sacrificial layer 220, the second preliminary channel layer 320, the third sacrificial layer 230, and the third preliminary channel layer 330. The second sacrificial layer 220, the second preliminary channel layer 320, the third sacrificial layer 230, and the third preliminary channel layer 330 may be subsequently removed from the second region R2. An additional sacrificial layer may be formed on the first preliminary channel layer 310 of the second region R2, and then the fourth sacrificial layer 240 and the fourth preliminary channel layer 340 may be sequentially stacked on the third preliminary channel layer 330 of the first region R1 and also on the additional sacrificial layer of the second region R2. Therefore, the first to fourth preliminary channel layers 310 to 340 may be provided on the first region R1, and the first and fourth preliminary channel layers 310 and 340 may be provided on the second region R2.

The processes discussed with reference to FIGS. 10A to 14A may be performed to fabricate a semiconductor device of FIGS. 4A and 4B.

A semiconductor device may be achieved in the form of an SRAM device. Alternatively, the semiconductor device may be achieved in the form of a driving device that drives an electronic apparatus. For example, the semiconductor device may be achieved in the form of a display driving integrated circuit.

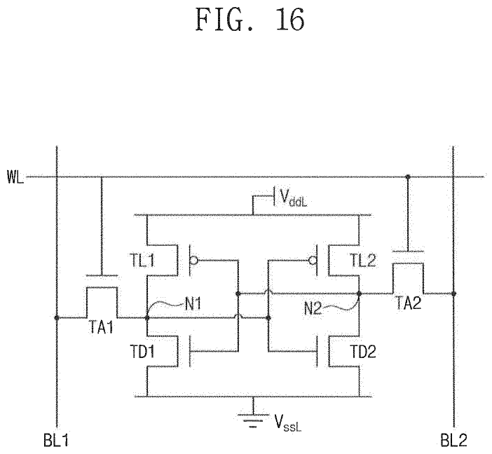

FIG. 16 illustrates an equivalent circuit diagram of an SRAM cell included in a semiconductor device according to an exemplary embodiment of the present inventive concepts. The SRAM cell included in the semiconductor device may be a CMOS SRAM cell.

Referring to FIG. 16, an SRAM cell may include a first load transistor TL1, a first driver transistor TD1, a second load transistor TL2, a second driver transistor TD2, a first access transistor TA1, and a second access transistor TA2. In an exemplary embodiment, the first and second load transistors TL1 and TL2 may be PMOS transistors. The first and second driver transistors TD1 and TD2 and the first and second access transistors TA1 and TA2 may be NMOS transistors.

A first node N1 may be connected to a first source/drain of the first load transistor TL1 and a first source/drain of the first driver transistor TD1. A power line V_{ddL} may be connected to a second source/drain of the first load transistor TL1. A ground line V_{ssL} may be connected to a second source/drain of the first driver transistor TD1. The first load transistor TL1 and the first driver transistor TD1 may have their gates electrically connected to each other. The first load transistor TL1 and the first driver transistor TD1 may constitute a first inverter. The first inverter may have an input terminal corresponding to the electrically connected gates of the first load and driver transistors TL1 and TD1, and an output terminal corresponding to the first node N1.

A second node N2 may be connected to a first source/drain of the second load transistor TL2 and to a first source/drain of the second driver transistor TD2. The power line V_{ddL}, may be connected to a second source/drain of the second load transistor TL2. The ground. line V_{ssL} may be connected to a second source/drain of the second driver transistor TD2. The second load transistor TL2 and the second driver transistor TD2 may have their gates electrically connected to each other. The second load transistor TL2 and the second driver transistor TD2 may constitute a second inverter. The second inverter may have an input terminal corresponding to the electrically connected gates of the second load and driver transistors TL2 and TD2, and an output terminal corresponding to the second node N2.

The first and second inverters may be connected to each other to constitute a latch structure. In this embodiment, the gates of the first load and driver transistors TL1 and TD1 may be electrically connected to the second node N2. The gates of the second load and driver transistors TL2 and TD2 may be electrically connected to the first node N1 The first source/drain of the first access transistor TA1 may be connected to the first node N1. The second source/drain of the first access transistor TA1 may be connected to a first bit line BL1. The first source/drain of the second access transistor TA2 may be connected to the second node N2, and the second source/drain of the second access transistor TA2 may be connected to a second bit line BL2. The first and second access transistors TA1 and TA2 may have their gates electrically connected to a word line WL. Therefore, the SRAM cell may be achieved.

The SRAM cell of the equivalent circuit diagram shown in FIG. 16 may be formed in various shapes on a substrate. The following will describe an example in which a substrate is provided thereon with an SRAM cell included in a semiconductor device according to an exemplary embodiment of the present inventive concepts. FIG. 17 illustrates a plan view showing a layout of the SRAM cell depicted in FIG. 16.

Referring to FIG. 17, an SRAM cell included in a semiconductor substrate may extend in a second direction Y and include first, second, third, and fourth semiconductor structures SS1, SS2, SS3, and SS4 that are spaced apart from each other in a first direction X. In an exemplary embodiment, the first and fourth semiconductor structures SS1 and SS4 may be formed on a P-type well region PW. The second and third semiconductor structures SS2 and SS3 may be formed on an N-type well region NW.

A first gate structure GS1 may be disposed on the first and second semiconductor structures SS1 and SS2. The first gate structure GS1 may extend in the first direction X. The first gate structure GS1 may surround the first and second semiconductor structures SS1 and SS2.

A first source/drain may be thrilled on the first semiconductor structure SS1 on opposite sides in the second direction Y of the first gate structure GS1. The first gate structure GS1, the first semiconductor structure SS1, and the first source/drain may constitute a first driver transistor TD1. The first driver transistor TD1 may be an NMOS transistor.

A second source/drain may be formed on the second semiconductor structure SS2 on opposite sides in the second direction Y of the first gate structure GS1. The first gate structure GS1, the second semiconductor structure SS2, and the second source/drain may constitute a first load transistor TL1. The first load transistor TL1 may be a PMOS transistor.

A second gate structure GS2 may be disposed on the first semiconductor structure SS1. The second gate structure GS2 may extend in the first direction X. The second gate structure GS2 may be spaced apart in the second direction Y from the first gate structure GS1. The second gate structure GS2 may surround the first semiconductor structure SS1.

A third source/drain may be formed on the first semiconductor structure SS1 on opposite sides in the second direction Y of the second gate structure GS2. The second gate structure GS2, the first semiconductor structure SS1, and the third source/drain may constitute a first access transistor TA1. In an exemplary embodiment, the first access transistor TA1 may be an NMOS transistor.

A third gate structure GS3 may be disposed on the third and fourth semiconductor structures SS3 and SS4. The third gate structure GS3 may extend in the first direction X and may be spaced apart in the first direction X from the second gate structure GS2. The third gate structure GS3 may surround the third and fourth semiconductor structures SS3 and SS4.

A fourth source/drain may be formed on the third semiconductor structure SS3 on opposite sides in the second direction Y of the third gate structure GS3. The third gate structure GS3, the third semiconductor structure SS3, and the fourth source/drain may constitute a second load transistor TL2. In an exemplary embodiment, the second load transistor TL2 may be a PMOS transistor.

A fifth source/drain may be formed on the fourth semiconductor structure SS4 on opposite sides in the second direction Y of the third gate structure GS3. The third gate structure GS3, the fourth semiconductor structure SS4, and the fifth source/drain may constitute a second driver transistor TD2. In an exemplary embodiment, the second driver transistor TD2 may be an NMOS transistor.

A fourth gate structure GS4 may be disposed on the fourth semiconductor structure SS4. The fourth gate structure GS4 may extend in the first direction X and may be spaced apart in the first direction X from the first gate structure GS1. The fourth gate structure GS4 may be spaced apart in the second direction Y from the third gate structure GS3. The fourth gate structure GS4 may surround the fourth semiconductor structure SS4.

A sixth source/drain may be formed on the fourth semiconductor structure SS4 on opposite sides in the second direction Y of the fourth gate structure GS4. The fourth gate structure GS4, the fourth semiconductor structure SS4, and the sixth source/drain may constitute a second access transistor TA2. In an exemplary embodiment, the second access transistor TA2 may be an NMOS transistor.

The first semiconductor structure SS1 and the second semiconductor structure SS2 may be electrically connected to each other through a first bridge contact BC1. The first bridge contact BC1 may be electrically connected through a first gate contact GC1 to the third gate structure GS3.

The third semiconductor structure SS3 and the fourth semiconductor structure SS4 may be electrically connected to each other through a second bridge contact BC2. The second bridge contact BC2 may be electrically connected through a second gate contact GC2 to the first gate structure GS1.

Vertically stacked channel layers may be included in the first and second load transistors TL1 and TL2, the first and second driver transistors TD1 and TD2, and the first and second access transistors TA1 and TA2, which transistors are achieved on the first to fourth semiconductor structures SS1 to SS4. At least one of the first and second load transistors TL1 and TL2, the first and second driver transistors TD1 and TD2, and the first and second access transistors TA1 and TA2, may include an amount of channel layers that is different from the amount of channel layers included in the other transistors. For example, the number of channel layers included in the first and second driver transistors TD1 and TD2 which may be configured in the form of NMOS transistors and in the first and second access transistors TA1 and TA2 which may be configured in the form of NMOS transistors may be greater than that of channel layers included in the first and second load transistors TL1 and TL2 which may be configured in the form of PMOS transistors.

A first transistor and a second transistor included in a semiconductor device may be any two of the transistors TL1, TL2, TD1, TD2, TA1, and TA2 shown in FIG. 17. For example, the first transistor having a large number of channel layers may be the first and second driver transistors TD1 and TD2 which may be configured in the form of NMOS transistors shown in FIG. 17. The second transistor having a relatively smaller number of channel layers may be the first and second load transistors TL1 and TL2 which may be configured in the form of PMOS transistors shown in FIG. 17. In one exemplary embodiment, the first transistor and the second transistor may respectively be the first driver transistor TD1 and the first load transistor TL1 that share a single first gate structure GS1. In certain exemplary embodiments, the amount of channel layers included in the first and second driver transistors TD1 and TD2 which may be configured in the form of NMOS transistors may be greater than the amount of channel layers included in the first and second load transistors TL1 and TL2 which may be configured in the form of PMOS transistors. This may result in improvement of write operating characteristics of the SRAM cell included in the semiconductor device. However, the exemplary embodiments of the present inventive concepts are not limited to the semiconductor device including the SRAM cell, but may be applicable to any other semiconductor device that includes a plurality of transistors.

According to some exemplary embodiments of the present inventive concepts, as discussed above, the amount of channel layers of the first and second driver transistors TD1 and TD2 which may be configured in the form of NMOS transistors may be greater than the amount of channel layers of the first and second load transistors TL1 and TL2 which may be configured in the form of PMOS transistors. This may result in improvement of the write operating characteristics of the SRAM cell included in the semiconductor device.

According to exemplary embodiments of the present inventive concepts, a semiconductor device may be formed to include transistors having different amounts of channel layers and thus may improve in electrical characteristics.

According to exemplary embodiments of the present inventive concepts, a method of fabricating a semiconductor device may use simple processes, such as deposition and etching, to form transistors having different numbers of channel layers.

Although the present invention has been described in connection with the exemplary embodiments of the present inventive concepts illustrated in the accompanying drawings, it will be understood by one of ordinary skill in the art that variations in form and detail may be made therein without departing from the spirit and essential feature of the present inventive concepts. The above disclosed exemplary embodiments should thus be considered illustrative and not restrictive.

What is claimed is:

1. A semiconductor device, comprising:
a substrate;
an insulating layer disposed on the substrate; and
a first semiconductor structure and a second semiconductor structure disposed on the insulating layer, wherein
each of the first and second semiconductor structures includes:
a gate electrode on the insulating layer;
a plurality of channel layers that are surrounded by the gate electrode and stacked in a direction perpendicular to a top surface of the insulating layer; and
a plurality of dielectric layers disposed between the gate electrode and the channel layers, and
an amount of the channel layers provided in the first semiconductor structure is greater than the amount of the channel layers provided in the second semiconductor structure.

2. The semiconductor device of claim wherein an uppermost channel layer of the first semiconductor structure is located at a same level as an uppermost channel layer of the second semiconductor structure.

3. The semiconductor device of claim 2, wherein a lowermost channel layer of the first semiconductor structure is located at a higher level than a lowermost channel layer of the second semiconductor structure.

4. The semiconductor device of claim 2, wherein a lowermost channel layer of the first semiconductor structure is located at a same level as a lowermost channel layer of the second semiconductor structure.

5. The semiconductor device of claim 4, wherein a bottom end of the gate electrode of the first semiconductor structure is located at a same level as a bottom end of the gate electrode of the second semiconductor structure.

6. The semiconductor device of claim 1, Wherein an uppermost channel layer of the first semiconductor structure is located at a higher level than an uppermost channel layer of the second semiconductor structure.

7. The semiconductor device of claim 6, wherein a top end of the gate electrode of the first semiconductor structure is located at a higher level than a top end of the gate electrode of the second semiconductor structure.

8. The semiconductor device of claim 1, wherein each of the channel layers of the second semiconductor structure is located at a same level as one of the channel layers of the first semiconductor structure.

9. The semiconductor device of claim 1, wherein each of the first and second semiconductor structures further comprises source/drain electrodes positioned on opposite sides of the gate electrode,
wherein the source/drain electrodes are connected to channel layers that horizontally penetrate the gate electrode.

10. The semiconductor device of claim 1, wherein
the first semiconductor structure is provided in a form of an NMOS transistor, and
the second semiconductor structure is provided in a form of a PMOS transistor.

11. The semiconductor device of claim 1, wherein the gate electrode of the first semiconductor structure is connected to the gate electrode of the second semiconductor structure.

12. A semiconductor device, comprising:
a substrate;
a first transistor disposed on an NMOS region of the substrate;
a second transistor disposed on a PMOS region of the substrate;
each of the first and second transistors including:
a first channel layer positioned at a first distance from a top surface of the substrate;
a second channel layer positioned at a second distance from the top surface of the substrate, the second distance being greater than the first distance; and
a plurality of source; drain electrodes connected to opposite sides of the first channel layer and to opposite sides of the second channel layer; and
a gate structure surrounding the first and second channel layers of each of the first and second transistors,
wherein the first transistor further includes a third channel layer below the second channel layer, and
wherein, in the first transistor, the gate structure is positioned at a same level as the third channel layer.

13. The semiconductor device of claim 12, wherein, in the first transistor, the third channel layer is positioned between the first and second channel layers.

14. The semiconductor device of claim 13, wherein a first spacing distance between the first channel layer and the third channel layer is the same as a second spacing distance between the second channel layer and the third channel layer.

15. The semiconductor device of claim 13, wherein, in the second transistor, the gate structure is disposed between the first channel layer and the second channel layer.

16. The semiconductor device of claim 12, wherein, in the first transistor, the third channel layer is below the second channel layer.

17. The semiconductor device of claim 12, further comprising a dielectric layer disposed between the gate structure and each of the first to third channel layers, the dielectric layer being configured to insulate the gate structure from each of the first to third channel layers.

18. The semiconductor device of claim 12, further comprising an insulating layer disposed between the substrate and the first and second transistors.

19. A semiconductor device, comprising:
a substrate;
a first transistor disposed on an NMOS region of the substrate; and
a second transistor disposed on a PMOS region of the substrate, wherein
the first transistor includes:
a plurality of first channel layers stacked on the substrate; and
a plurality of first source/drain electrodes connected to opposite sides of the first channel layers,
the second transistor includes:
a plurality of second channel layers stacked on the substrate; and
a plurality of second source/drain electrodes connected to opposite sides of the second channel layers, an amount of the second channel layers being less than the amount of the first channel layers, and
a spacing distance between the substrate and an uppermost one of the first channel layers is the same as the spacing distance between the substrate and an uppermost one of the second channel layers.

20. The semiconductor device of claim 19, wherein each of the second channel layers is located at a same level as one of the first channel layers, and
wherein a spacing distance between the substrate and a lowermost first channel layer is less than the spacing distance between the substrate and a lowermost second channel layer.
